(19) United States
(12) Patent Application Publication
(10) Pub. No.: US 2011/0002185 A1
(43) Pub. Date: Jan. 6, 2011

(54) Semiconductor device with control circuit controlling controlled circuit to the same potential

(75) Inventor: Hiroyuki Matsuno, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/801,542

(22) Filed: Jun. 14, 2010

(30) Foreign Application Priority Data
Jul. 2, 2009 (JP) 2009-157377

(51) Int. Cl. G11C 7/00; H03K 3/00; H03K 17/00

(52) U.S. Cl. 365/222; 327/218; 327/415; 365/230.08

(57) ABSTRACT

A device includes a first circuit, a second circuit, and a control circuit controlling the first and the second circuits. The control circuit controls a plurality of output signals of the second circuit so as to have the same potential when the control circuit activates the first circuit and inactivates the second circuit.

This application is based upon and claims the benefit of priority from Japanese patent application No. 2009-157377, filed on Jul. 2, 2009, the disclosure of which is incorporated herein in its entirety by reference.

### BACKGROUND OF THE INVENTION

1. Field of the Invention

This invention relates to a semiconductor device.

2. Description of Related Art

Semiconductor devices have been widely used in not only a personal computer but also a mobile unit such as a cellular mobile phone or the like. In a use of such s mobile unit, it is especially important to decrease power consumption.

In a conventional art, an address latch circuit relating to an address signal used in the, semiconductor device holds the address signal on previously being operated although it does not involve in the operation.

In the manner which is described above, the address latch circuit holds the address signal although it does not involve in the operation and supplies a held address signal to an output side. Accordingly, when there is a short-circuit between address wires connected to the output side of the address latch circuit and when the address signal held in the address latch circuit causes a potential difference between the address wires occur (has a plurality of bits different from each other), a leakage current flows between the address wires. In other words, unintended power consumption occurs.

JP-A-11-195294, which corresponds to U.S. Pat. No. 6,182,635, discloses a technique, in a row address latch circuit, for making an output level thereof a logic low level after passing an output thereof to the following pre-decoder for the sake of high-speed operation.

The technique described in U.S. Pat. No. 6,182,635 makes the output level of the row address latch circuit the logic low level for a predetermined interval while it involves in the operation for the sake of the high-speed operation, but does not teach decreasing the unintended power consumption when it does not involves in the operation.

### SUMMARY

The present invention seeks to solve one or more of the above problems, or to improve upon those problems at least in part.

In one embodiment, there is provided a device that includes a first circuit, a second circuit producing a plurality of output signals, and a control circuit controlling the first circuit and the second circuit. The control circuit controls the plurality of output signals of the second circuit so as to have the same potential while the control circuit repeatedly carries out a first operation by activating the first circuit and by inactivating the second circuit.

In another embodiment, there is provided a method that comprises controlling a device. The device comprises a plurality of memory cells, a row latch circuit relating to an address signal, a column latch circuit relating to the address signal, and external terminals. The controlling comprises carrying out a normal operation where the memory cells output data to said external terminals by accessing the memory cells using information held in the row latch circuit and in the column latch circuit, and carrying out a refresh operation where the memory cells do not output data to the external terminals although the memory cells are accessed using information held in the row latch circuit. The controlling controls a plurality of output signals of the column latch circuit so as to have the same potential while the refresh operation is repeatedly carried out.

In still another embodiment, there is provided a device that comprises a semiconductor device. The semiconductor device comprises a controlled circuit having a plurality of output lines, and a control circuit controlling the controlled circuit. The control circuit puts the controlled circuit into an inactive state and controls the plurality of output lines so as to have the same potential while the control circuit repeatedly performs a first operation by activating other circuits other than the controlled circuit.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing schematic structure of a semiconductor memory device according to a first exemplary embodiment of this invention;

FIG. 2 is a block diagram showing schematic structure of a bank included in the semiconductor memory device illustrated in FIG. 1;

FIG. 3 is a timing chart for use in describing operation where the bank illustrated in FIG. 2 is supplied with a self-refresh signal;

FIG. 4 is a time chart for use in describing operation where the bank illustrated in FIG. 2 is supplied with a power down signal;

FIG. 5 is a circuit diagram showing one configuration example of a row latch circuit included in the bank illustrated in FIG. 2;

FIG. 6 is a circuit diagram showing one configuration example of a column latch circuit included in the bank illustrated in FIG. 2;

FIG. 7 is a circuit diagram showing another configuration example of a row latch circuit included in the bank illustrated in FIG. 2; and

FIG. 8 is a circuit diagram showing another configuration example of a column latch circuit included in the bank illustrated in FIG. 2.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

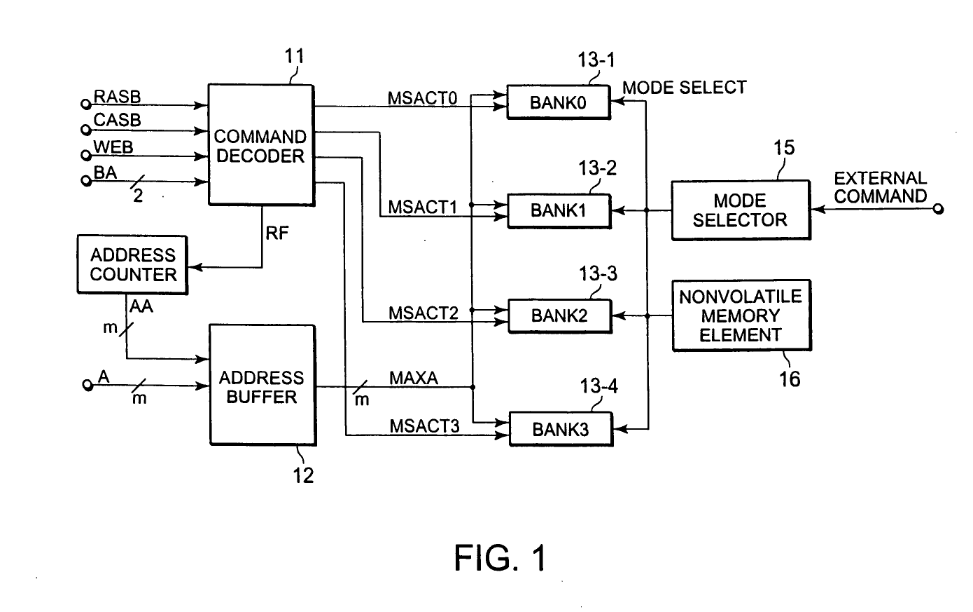

FIG. 1 shows a schematic structure of a semiconductor memory device according to a first exemplary embodiment of this invention.

The illustrated semiconductor memory device comprises a command decoder 11 receiving a command supplied from an outside, an address buffer 12 receiving an address, a plurality of (herein, four) banks 13-1, 13-2, 13-3, and 13-4, an address counter 14 generating an internal address, a mode selector 15 carrying out a mode selection due to an external command, and a nonvolatile memory element 16. The four banks 13-1 to 13-4 are called first through fourth banks which are depicted at BANK0, BANK1, BANK2, and BANK3, respectively.

Although the semiconductor memory device illustrated in FIG. 1 is configured with a 4-bank structure comprising the four banks 13-1 to 13-4, the number of banks may be one or any number which is not less than two.

The command decoder 11 is supplied with control signals RASB, CASB, WEB, and a bank address BA. The command decoder 11 specifies commands on the basis of a combination of the control signals RASB, CASB, and WEB. The commands include first through fourth operation commands MSACT0, MSACT1, MSACT2, and MSACT3, and a refresh command RF. In addition, the command decoder 11 determines, on the basis of the band address BA, one of the first through the fourth banks 13-1 to 13-4 to that a specified command should be delivered. In the example being illustrated, the bank address BA is 2 bits long.

Supplied with the refresh command RF from the command decoder 11, the address counter 14 performs a count operation to send a counted value as the internal address AA to the address buffer 12. In the example being illustrated, the internal address AA is m bits in length, where m represents a first integer which is not less than two.

The address buffer 12 selects one of an external address A supplied from outside and the internal address AA supplied from the address counter 14 to send a selected address MAXA to each of the first through the fourth banks 13-1 to 13-4. In the example being illustrated, each of the external address A and the selected address MAXA is m bits in length.

The mode selector 15 delivers, in accordance with the external command, a first mode select signal to each of the first through the fourth banks 13-1 to 13-4. The nonvolatile memory element 16 comprises, for example, a laser fuse or an anti-fuse. The nonvolatile memory element 16 delivers, in accordance with its state, namely, written information, a second mode select signal to each of the first through the fourth banks 13-1 to 13-4. Supplied from the mode selector 15 and from the nonvolatile memory element 16, the first and the second mode select signals are used for determining whether or not the semiconductor memory device carries out operation peculiar to this invention which will later be described (namely, controls output signals of a column latch circuit 23 so as to have the same potential).

Now, the description will proceed to structure of each of the first through the fourth banks 13-1 to 13-4. Hereafter, the first bank 13-1 will be representatively described because all of the first through the fourth banks 13-1 to 13-4 have the similar structure. For the sake of simplification, the first bank 13-1 will be merely called a bank which is depicted at 13.

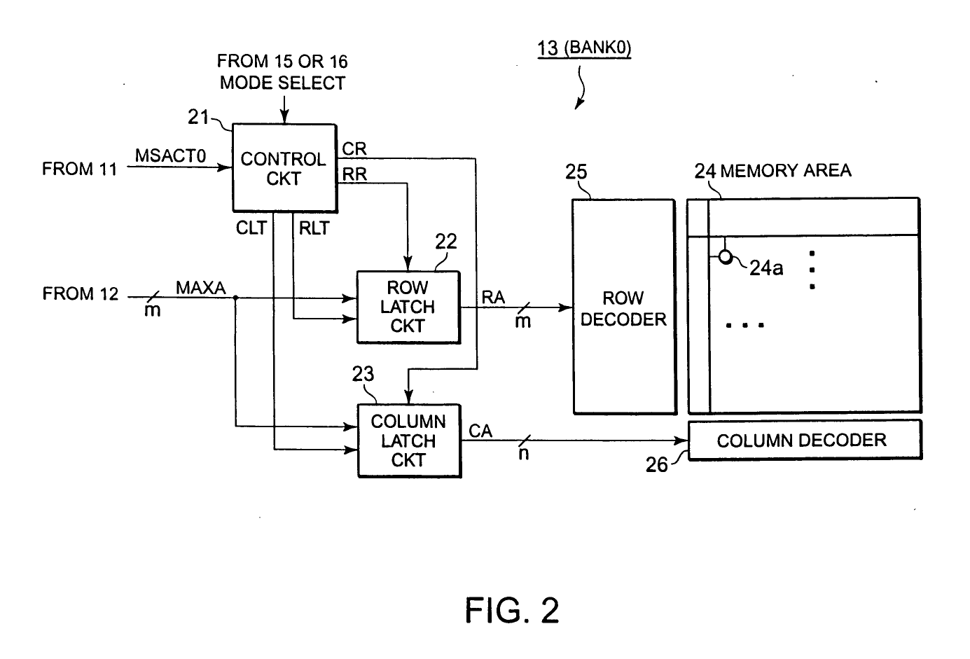

FIG. 2 is a block diagram showing schematic structure of the bank 13 included in the semiconductor memory device illustrated in FIG. 1. As shown in

FIG. 2, the bank 13 comprises a control circuit 21, a row latch circuit 22, a column latch circuit 23, a memory area 24, a row decoder 25, and a column decoder 26. In the example being illustrated, the row latch circuit 22 is called a first circuit while the column latch circuit 23 is called a second circuit. In addition, the column latch circuit 23 is also called a controlled circuit.

In accordance with the first operation command MSACT0 and the first or the second mode select signal supplied from the mode selector 15 or the nonvolatile memory element 16, the control circuit 21 controls the first circuit (the row latch circuit) 22 and the second circuit (the column latch circuit) 23 in the manner which will later become clear.

If there is no limitation due to the first or the second mode select signal, the control circuit 21 delivers a control signal to the row latch circuit 22 or the column latch circuit 23 in accordance with a type of the first operation command MSACT0 supplied from the command decoder 11 (FIG. 1).

Therefore, both of the row latch circuit 22 and the column latch circuit 23 relating to the address signal are activated, a normal operation is therefore carried out where memory cells 24a of the memory area 24 are accessed on the basis of information held in these latch circuits 22 and 23 and data are transmitted/received to/from the outside via external terminals (not shown). Alternatively, the row latch circuit 22 is activated and the column latch circuit 23 is inactivated, a refresh operation serving as a first operation is therefore repeatedly carried out where data are not transmitted/received to/from the outside although the memory cells 24a of the memory area 24 are accessed on the basis of information held in the row latch circuit 22.

For example, it will be assumed that the first operation command MSACT0 is an active signal ACT. In this event, the control circuit 21 delivers a row latch signal RLT to the row latch circuit 22 to make the row latch circuit 22 latch the selected address MAXA. The row latch circuit 22 produces the latched address MAXA as a row address RA which is m bits long. The active signal ACT is a command for activating a word line corresponding to an address input.

It will be presumed that the first operation command MSACT0 is a read-out signal READ or a write-in signal WRITE. In this event, the control circuit 21 delivers a column latch signal CLT to the column latch circuit 23 to make the column latch circuit 23 latch the selected address MAXA. The column latch circuit 23 produces the latched address MAXA as a column address CA which is n bits long, where n represents a second integer which is not less that two. The second integer n may be equal to or less than the first integer m. The read-out signal READ is a command for reading data out of a column corresponding to the address input. The write-in signal WRITE is a command for writing data in a column corresponding to the address input.

The memory area 24 comprises a memory cell array which comprises a lot of memory cells 24a. Each of the memory cells 24a stores one bit. The lot of memory cells 24a are arranged in a matrix fashion with 2^{m} rows and 2ⁿ columns.

It will be assumed that the first operation command MSACT0 is a self-refresh signal SELF. In this event, the control circuit 21 delivers the row latch signal RLT to the row latch circuit 22 to make the row latch circuit 22 latch the selected address MAXA and delivers a column reset signal CR to the column latch circuit 23. The self-refresh signal SELF is a command for switching the semiconductor memory device into a power saving mode where data in the memory cells are automatically refreshed.

Supplied the column reset signal CR from the control circuit 21, the column latch circuit 23 resets a signal held therein to make all of output signals for a plurality of output lines the same level (a high level or a low level). In the manner which is described above, on carrying out the self-refresh operation, all of output potentials on address wires of a column-based address become the same potential while the refresh operation is repeatedly carried out. Inasmuch as only the row-based address is used and a column-based address is not used on carrying out the self-refresh operation, such a control is available. Although any short-circuit occurs in address wires of the column-based address, a current does not flow therebetween, and it is therefore possible to decrease a consumed current. To make all of the output potentials of these address wires the same potential is carried out in all of the banks, namely, with respect to a plurality of column switches.

It will be presumed that the first operation command MSACT0 is a power down signal PWDN. In this event, the control circuit 21 delivers a row reset signal RR and the column reset signal CR to the row latch circuit 22 and the column latch circuit 23, respectively. The power down signal PWDN is a command for switching the semiconductor memory device to a power saving mode (a standby state). In this even, the refresh operation is not carried out.

Supplied with the row and the column reset signals RR and CR, respectively, the row latch circuit 22 and the column latch circuit 23 reset signals held therein to make all of output signals on a plurality of output lines thereof the same level (the high level or the low level). As a result, it is possible to reduce a consumed current in both of a case where address wires of the row-based address are shorted out and another case where address wires of the column-based address are shorted out.

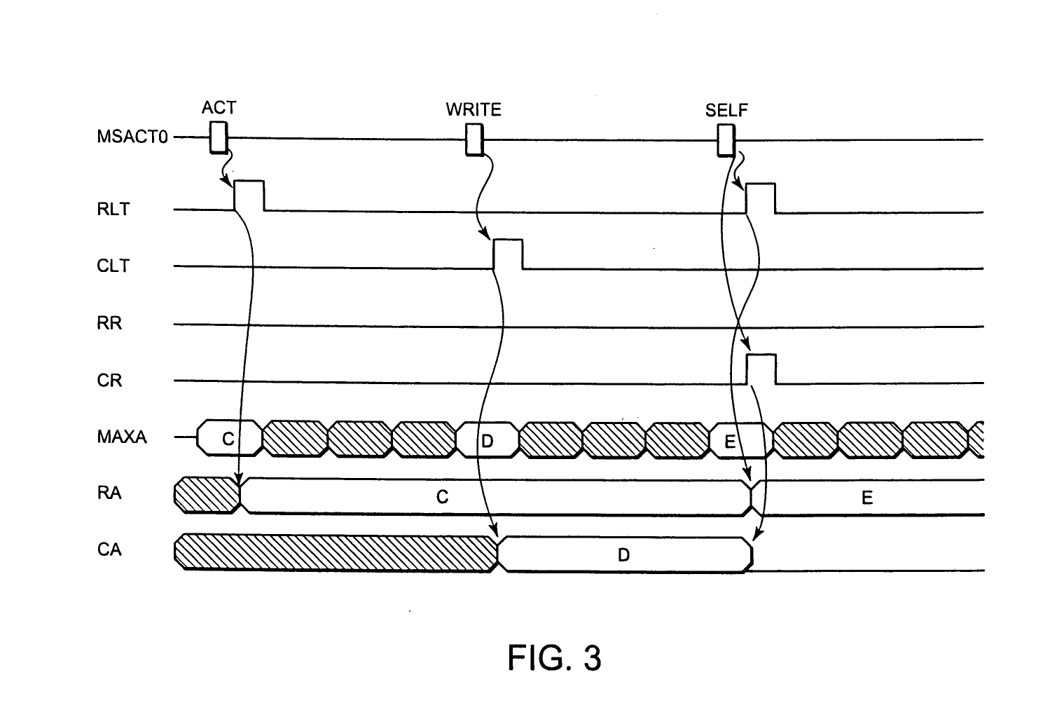

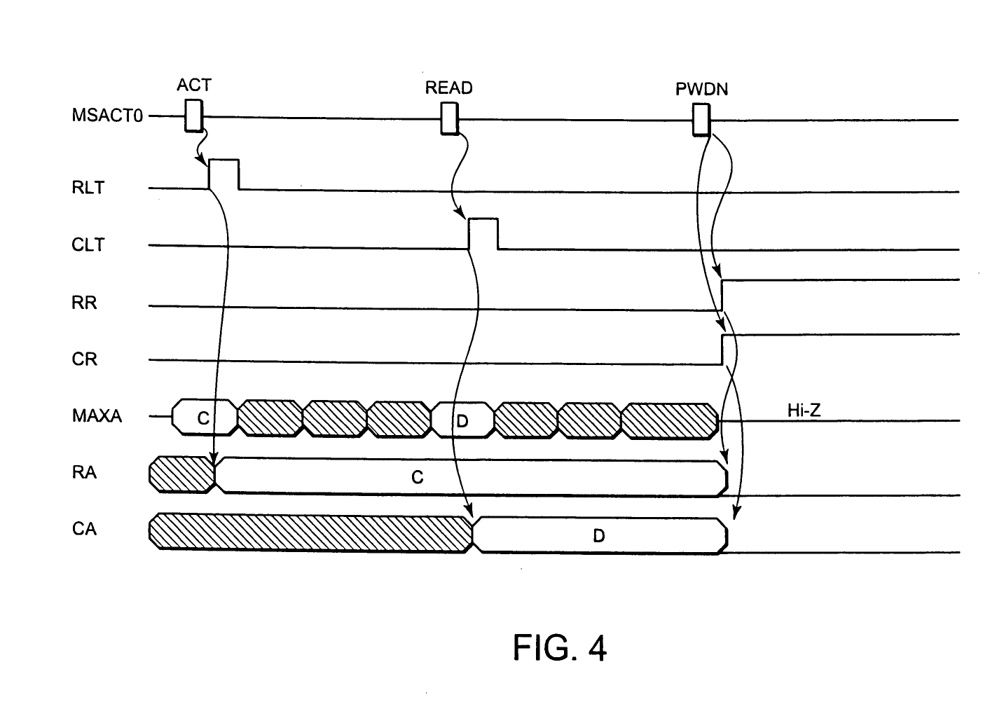

FIGS. 3 and 4 show variations in signal waveforms (signal timings) of the respective portions on the above-mentioned operations.

FIG. 3 shows operation waveforms in a case where the active signal ACT, the write-in signal WRITE, and the self-refresh signal SELF are successively supplied to the control circuit 21 as the first operation. command MSACT0.

Responsive to the active signal ACT, the control circuit 21 delivers the row latch signal RLT to the row latch circuit 22 to make the row latch circuit 22 latch the selected address MAXA of “C”.

Subsequently, responsive to the write-in signal WRITE, the control circuit 21 delivers the column latch signal CLT to the column latch circuit 23 to make the column latch circuit 23 latch the selected address MAXA of “D”.

Thereafter, responsive to the self-refresh signal SELF, the control circuit 21 delivers the row latch signal RLT and the column reset signal CR to the row latch circuit 22 and the column latch circuit 23, respectively, to make the row latch circuit 22 latch the selected address MAXA of “E” and to make the column latch circuit 23 reset.

FIG. 4 shows operation waveforms in a case where the active signal ACT, the read-out signal READ, and the power down signal PWDN are successively supplied to the control circuit 21 as the first operation command MSACT0.

Responsive to the active signal ACT, the control circuit 21 delivers the row latch signal RLT to the row latch circuit 22 to make the row latch circuit 22 latch the selected address MAXA of “C”.

Subsequently, responsive to the read-out signal READ, the control circuit 21 delivers the column latch signal CLT to the column latch circuit 23 to make column latch circuit 23 latch the selected address MAXA of “D”.

Thereafter, responsive to the power down signal PWDN, the control circuit 21 delivers the row and the column reset signals RR and CR to the row latch circuit 22 and the column latch circuit 23, respectively, to make both of the row latch circuit 22 and the column latch circuit 23 reset.

It will be assumed that the first and the second mode select signals supplied to the control circuit 22 designate a mode for limiting output of the row and the column reset signals RR and CR. In this event, supply of the row and the column reset signals RR and CR to the row latch circuit 22 and the column latch circuit 23 is inhibited. This can be implemented by a simple circuit using NAND circuits or the like.

Each of the row latch circuit 22 and the column latch circuit 23 may adopt a first method where one bit of the address is expressed by one wire or a second method where one bit of the address is expressed by two wires. The second method is called a complementary signal method.

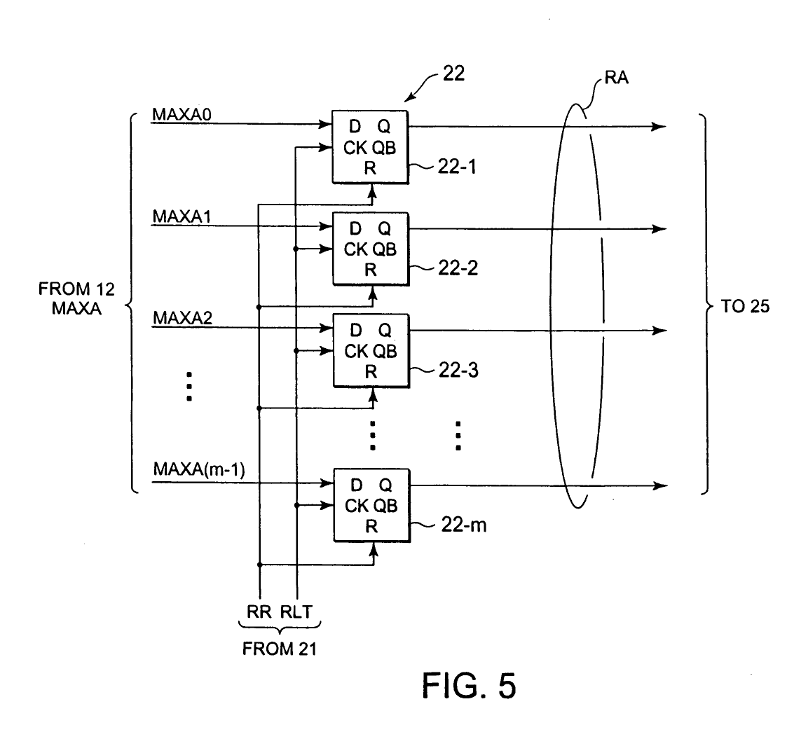

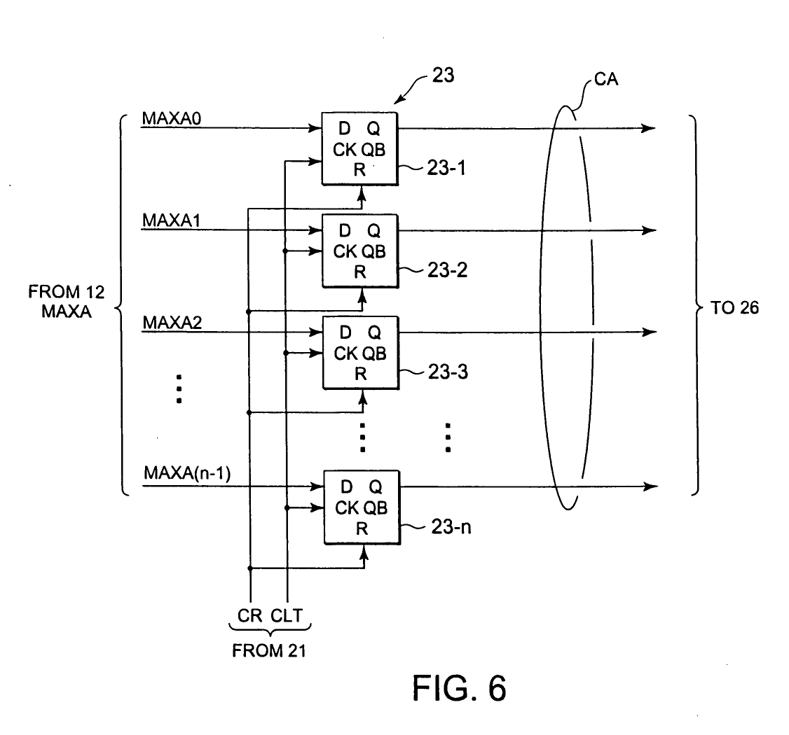

FIGS. 5 and 6 show the row latch circuit 22 and the column latch circuit 23, respectively, each of which adopts the first method where one bit of the address is expressed by one wire. As shown in FIG. 5, the row latch circuit 22 comprises first through m-th D-type flip-flops 22-1, 22-2, 22-3, . . . , and 22-m which correspond to the m bits of the selected address MAXA, respectively. Likewise, as shown in FIG. 6, the column latch circuit 23 comprises first through n-th D-type flip-flops 23-1, 23-2, 23-3, . . . , and 23-n which correspond to the n bits of the selected address MAXA, respectively.

In the row latch circuit 22 shown in FIG. 5, each of the first through the m-th D-type flip-flops 22-1 to 22-m has a clock terminal CK supplied with the row latch signal RLT from the control circuit 21 and a reset terminal R supplied with the row reset signal RR from the control circuit 21. With this structure, the first through the m-th D-type flop-flops 22-1 to 22-m latch, in response to the row latch signal RLT supplied from the control circuit 21, the m bits MAXA0 to MAXA(m-1) of the selected address MAXA supplied to input terminals D thereof to produce at output terminals Q latched signals, respectively, as the row address RA. In addition, responsive to the row reset signal RR supplied from the control circuit 21, each of the first through the m-th D-type flip-flops 22-1 to 22-m is reset. As a result, all of the output signals of the first through the m-th D-type flip-flops 22-1 to 22-m are controlled to the same potential.

Similarly, in the column latch circuit 23 shown in FIG. 6, each of the first through the n-th D-type flip-flops 23-1 to 23-n has a clock terminal CK supplied with the column latch signal CLT from the control circuit 21 and a reset terminal R supplied with the column reset signal CR from the control circuit 21. With this structure, the first through the n-th D-type flop-flops 23-1 to 23-n latch, in response to the column latch signal CLT supplied from the control circuit 21, the n bits MAXA0 to MAXA(n-1) of the selected address MAXA supplied to input terminals D thereof to produce at output terminals Q latched signals, respectively, as the column address CA. In addition, responsive to the column reset signal CR supplied from the control circuit 21, each of the first through the n-th D-type flip-flops is reset. As a result, all of the outputs of the first through the n-th D-type flip-flops 23-1 to 23-n are controlled to the same potential.

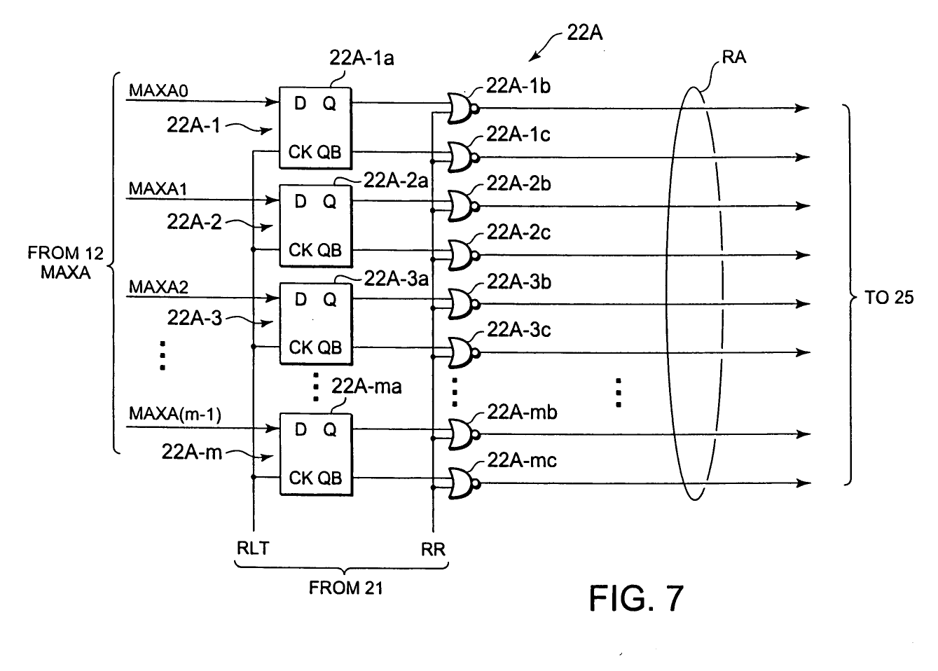

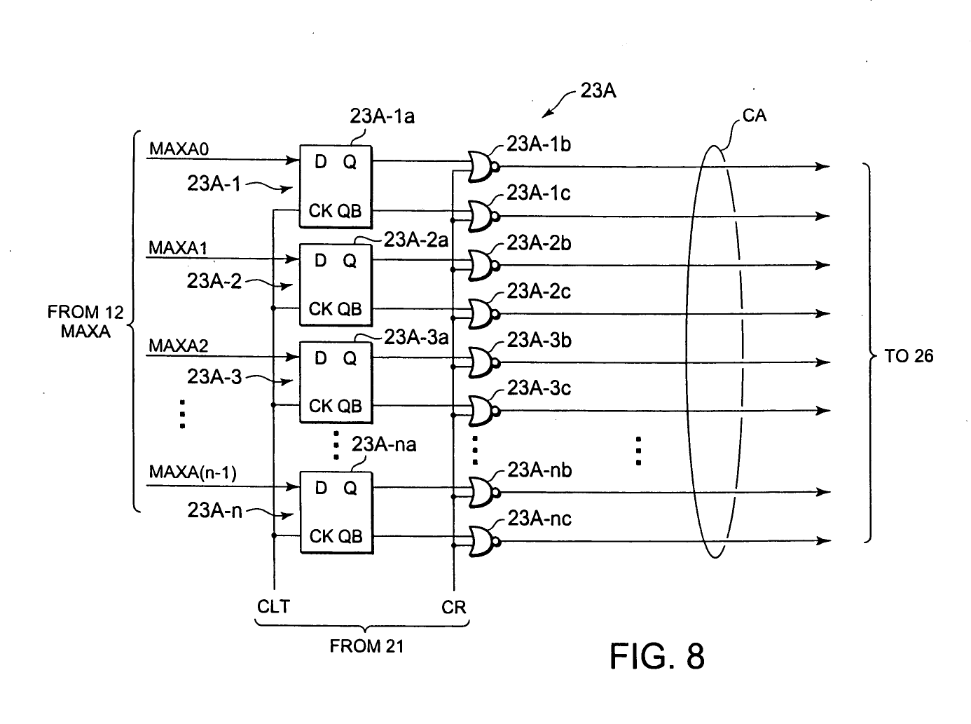

FIGS. 7 and 8 show a row latch circuit 22A and a column latch circuit 23A, respectively, each of which adopts the second method where one bit of the address is expressed by two wire. As shown in FIG. 7, the row latch circuit 22A comprises first through m-th D-type flip-flops 22A-1a, 22A-2a, 22A-3a, . . . , and 22A-ma which correspond to the m bits of the selected address MAXA, respectively, first through m-th primary NOR circuits 22A-1b, 22A-2b, 22A-3b, and 22A-mb which have primary input terminals connected to output terminals Q of the first through the m-th D-type flip-flops 22A-1a to 22A-ma, respectively, and first through m-th secondary NOR circuits 22A-1c, 22A-2c, 22A-3c, . . . , and 22A-mc which have primary input terminals connected to inverted output terminals QB of the first through the m-th D-type flip-flops 22A-1a to 22A-ma, respectively.

Likewise, as shown in FIG. 8, the column latch circuit 23A comprises first through n-th D-type flip-flops 23A-1a, 23A-2a, 23A-3a, . . . , and 23A-na which correspond to the n bits of the selected address MAXA, respectively, first through n-th primary NOR circuits 23A-1b, 23A-2b, 23A-3b, . . . , and 23A-nb which have primary input terminals connected to output terminals Q of the first through the n-th D-type flip-flops 23A-1a to 23A-na, respectively, and first through n-th secondary NOR circuits 23A-1c, 23A-2c, 23A-3c, . . . , and 23A-nc which are have primary input terminals connected to inverted output terminals QB of the first through the n-th D-type flip-flops 23A-1a to 23A-na, respectively. In the row latch circuit 22A shown FIG. 7, each of the first through the m-th D-type flop-flops 22A-1a to 22A-ma has a clock terminal CK supplied with the row latch signal RLT from the control circuit 21. Responsive to the row latch signal RLT from the control circuit 21, the first through the m-th D-type flop-flops 22A-1a to 22A-ma latch the m bits of the selected address MAXA supplied to input terminals D thereof. The first through the m-th primary NOR circuits 22A-1b to 22A-mb have the primary input terminals connected to the output terminals Q of the first through the m-th D-type flip-flops 22A-1a to 22A-ma, respectively, and secondary input terminals supplied with the row reset signal RR from the control circuit 21 in common. The first through the m-th secondary NOR circuits 22A-1c to 22A-mc have the primary input terminals connected to the inverted output terminals QB of the first through the m-th D-type flip-flops 22A-1a to 22A-ma, respectively, and secondary input terminals supplied with the row reset signal RR from the control circuit 21 in common. When the row reset signal RR is absent (the logic low level), complementary signals from the first through the m-th D-type flip-flops 22A-1a to 22A-ma are output with they logic-inverted by the first through the m-th primary NOR circuits 22A-1b to 22A-mc and the first through the m-th secondary NOR Circuits 22A-1c to 22A-mc. When the row reset signal RR is present (the logic high level), the complementary signals from the first through the m-th D-type flip-flops 22A-1a to 22A-ma are inhibited by the first through the m-th primary NOR circuits 22A-1b to 22A-mc and the first through the m-th secondary NOR circuits 22A-1c to 22A-mc. In the manner which is described above, all of the output signals of the row latch circuit 22A are controlled to the same potential (the logic low level).

Likewise, as shown in FIG. 8, each of the first through the n-th D-type flop-flops 23A-1a to 23A-na has a clock terminal CK supplied with the column latch signal CLT from the control circuit 21. Responsive to the column latch signal CLT from the control circuit 21, the first through the n-th D-type flop-flops 23A-1a to 23A-na latch the n bits of the selected address MAXA supplied to input terminals D thereof. The first through the n-th primary NOR circuits 23A-1b to 23A-nb have the primary input terminals connected to the output terminals Q of the first through the n-th D-type flip-flops 23A-1a to 23A-na, respectively, and secondary input terminals supplied with the column reset signal CR from the control circuit 21 in common. The first through the n-th secondary. NOR circuits 23A-1c to 23A-nc have the primary input terminals connected to the inverted output terminals QB of the first through the n-th D-type flip-flops 23A-1a to 23A-na, respectively, and secondary input terminals supplied with the column reset signal CR from the control circuit 21 in common.

When the column reset signal CR is absent (the logic low level), complementary signals from the first through the n-th D-type flip-flops 23A-1a to 23A-na are output with they logic-inverted by the first through the n-th primary NOR circuits 23A-1b to 23A-nc and the first through the n-th secondary NOR circuits 23A-1c to 23A-nc. When the column reset signal CR is present (the logic high level), the complementary signals from the first through the n-th D-type flip-flops 23A-1a to 23A-na are inhibited by the first through the n-th primary NOR circuits 23A-1b to 23A-nc and the first through the m-th secondary NOR circuits 23A-1c to 23A-nc. In the manner which is described above, all of the output signals of the column latch circuit 23A are controlled to the same potential (the logic low level).

By using NAND circuits in lieu of the NOR circuits, it is possible to make all of the output signals of the latch circuit the logic high level as the same potential when the reset signal of the logic low level is supplied.

Although a circuit system of the D-type flip-flops is adopted as the latch circuits in the above-mentioned exemplary embodiment, the circuit system is not limited to it. For example, a known circuit system of a JK-type or a T-type flip-flops may be adopted as the latch circuits.

In the manner which is described above, in the semiconductor memory device according to the exemplary embodiment of this invention, it is possible to reduce a consumed current by eliminating a leakage current between address wires although the address wires are shorted out. This is because the semiconductor memory device makes the output potentials of bits of an unused address signal (among a plurality of output signal lines of the address signal, among complementary output signal lines of the address signal) the same potential for a predetermined duration.

While the invention has been particularly shown and described with reference to exemplary embodiments thereof, the invention is not limited to these embodiments. It will be understood by those of ordinary skilled in the art that various changes in form and details may be made therein without departing from the sprit and scope of the present invention as defined by the claims.

For example, although the description is made about the semiconductor memory device in the above-mentioned exemplary embodiments, the technical ides of this application is not limited to control of the output signal lines in an address latch circuit relating to an address signal. For example, this invention can be applicable to the semiconductor products in general such as a CPU (Central Processing Unit), an MCU (Micro Control Unit), a DSP (Digital Signal Processor), an ASIC (Application Specific Integrated Circuit), an ASSP (Application Specific Standard Circuit) each comprising a plurality of memory elements as a memory function, and so on. In addition, a device to which this invention is applicable can be applied to semiconductor devices such as a SOC (System On Chip), an MCP (Multi Chip Package), a POP (Package On Package), or the like. The transistors used to the latch circuits or the like may be field effect transistors (FETs) or bipolar transistors. The transistors can be applicable to various FETs such as not only MOS (Metal Oxide Semiconductor) but also MIS (Metal-Insulator Semiconductor), TFT (Thin Film Transistor), or the like. The transistors may be transistors other than FETs. Furthermore, a semiconductor substrate is not restricted to a P-type semiconductor substrate and may be other semiconductor substrates such as an N-type semiconductor substrate and a semiconductor substrate having a SOI (Silicon on Insulator) structure.

What is claimed is:

1. A device comprising:
a first circuit;
a second circuit producing a plurality of output signals; and
a control circuit controlling said first circuit and said second circuit, said control circuit controlling the plurality of output signals of said second circuit so as to have the same potential while said control circuit repeatedly carries out a first operation by activating said first circuit and by inactivating said second circuit.

2. The device as claimed in claim 1, wherein the plurality of output signals are one or more pairs of complementary signals when said second circuit is activated.

3. The device as claimed in claim 2, wherein said second circuit comprises a plurality of logic circuits each having one input terminal supplied with one of the complementary signals and another input terminal supplied with a reset signal from said control circuit in common.

4. The device as claimed in claim 1, wherein said control circuit controls the plurality of output signals between a first state where different potentials may be taken and a second state having the same potential.

5. The device as claimed in claim 4, wherein said second circuit comprises a plurality of flip-flops producing the plurality of output signals, each of said flip-flops having a reset terminal supplied with a reset signal from said control circuit.

6. The device as claimed in claim 5, wherein each of said plurality of flip-flops comprises a D-type flip-flop.

7. The device as claimed in claim 1, wherein said first circuit and said second circuit comprises a row latch circuit and a column latch circuit which relate to an address signal, respectively.

8. The device as claimed in claim 7, the address signal is n bits in length, where n represents a positive integer which is not less than two, wherein said column latch circuit comprises n flip-flops having n input terminals supplied with the n bits of the address signal, respectively, each of said n flip-flops having a reset terminal supplied with a reset signal from said control circuit.

9. The device as claimed in claim 8, wherein each of said n flip-flops comprises a D-type flip-flop.

10. The device as claimed in claim 7, the address signal is n bits in length, where n represents a positive integer which is not less than two, wherein said column latch circuit comprises:
n flip-flops having n input terminals supplied with the n bits of the address signal, respectively, each of said n flip-flops having an output terminal and an inverted output terminal;
n primary logic circuits having n primary input terminals connected to the output terminals of said n flip-flops, respectively, each of said n primary logic circuits having a secondary input terminal supplied with a reset signal from said control circuit; and
n secondary logic circuits having n primary input terminals connected to the inverted output terminals of said n flip-flops, respectively, each of said n secondary logic circuits having a secondary input terminal supplied with the reset signal from said control circuit,
whereby said n primary logic circuits and said n secondary logic circuits produce, as the plurality of output signals, n pairs of complementary signals.

11. The device as claimed in claim 10, wherein each of said n flip-flops comprises a D-type flip-flop.

12. The device as claimed in claim 10, wherein each of said n primary logic circuits comprises a NOR circuit and each of said n secondary logic circuits comprises a NOR circuit, said reset signal having a logic high level.

13. The device as claimed in claim 10, wherein each of said n primary logic circuits comprises a NAND circuit and each of said n secondary logic circuits comprises a NAND circuit, said reset signal having a logic low level.

14. A method comprising: controlling a device,
wherein said device comprises a plurality of memory cells, a row latch circuit relating to an address signal, a column latch circuit relating to the address signal, and external terminals,
said controlling comprising:
carrying out a normal operation where said memory cells output data to said external terminals by accessing said memory cells using information held in said row latch circuit and in said column latch circuit; and
carrying out a refresh operation where said memory cells do not output data to said external terminals although said memory cells are accessed using information held in said row latch circuit,
wherein said controlling controls a plurality of output signals of said column latch circuit so as to have the same potential while said refresh operation is repeatedly carried out.

15. The method as claimed in claim 14, the address signal being n bits in length, where n represents an integer which is not less than two, said column latch circuit comprising n flip-flops supplied with the n bits of the address signal, respectively, each of said n flip-flops having a reset terminal, wherein said controlling comprises supplying a reset signal to the reset terminal of each of said n flip-flops while said refresh operation is repeatedly carried out.

16. The method as claimed in claim 14, the address signal being n bits in length, where n represents an integer which is not less than two,
wherein said column latch circuit comprises:
n flip-flops supplied with the n bits of the address signal, respectively, each of said n flip-flops having an output terminal and an inverted output terminal:
n primary logic circuits having n primary input terminals connected to the output terminals of said n flip-flop, each of n said n primary logic circuits having a secondary input terminal; and
n secondary logic circuits having n primary input terminals connected to the inverted output terminals of said n flip-flops, each of said n secondary logic circuit having a secondary input terminal,
wherein said controlling comprises supplying a reset signal to the secondary input terminal of each of said n primary logic circuits and to the secondary input terminal of each of said n secondary logic circuits while said refresh operation is repeatedly carried out.

17. A device comprising a semiconductor device, said semiconductor device comprising:
a controlled circuit having a plurality of output lines; and
a control circuit controlling said controlled circuit, said control circuit putting said controlled circuit into an inactive state and controlling the plurality of output lines so as to have the same potential while said control circuit repeatedly performs a first operation by activating other circuits other than said controlled circuit.

18. The device as claimed in claim 17, wherein said control circuit controls the plurality of output lines so as to have the same potential for the duration of a standby state of said semiconductor device.

19. The device as claimed in claim 17, wherein said first operation is an operation where said semiconductor device does not deliver data to external terminals.

20. The device as claimed in claim 17, wherein said controlled circuit comprises a column latch circuit relating to an address signal.
